(19) United States
(12) Patent Application Publication
(10) Pub. No.: US 2006/0084257 A1
(43) Pub. Date: Apr. 20, 2006

(54) Dye sensitization photoelectric converter and process for fabricating the same

(76) Inventors: Yuichi Tokita, Kanagawa (JP); Yusuke Suzuki, Kanagawa (JP); Masahiro Morooka, Kanagawa (JP); Kenichi Ishibashi, Kanagawa (JP); Kazuhiro Noda, Kanagawa (JP)

Correspondence Address: WOLF GREENFIELD & SACKS, PC;FEDERAL RESERVE PLAZA, 600 ATLANTIC AVENUE, BOSTON, MA, 02210-2211, US

(21) Appl. No.: 10/540,629

(22) PCT Filed: Dec. 12, 2003
(86) PCT No.: PCT/JP03/15965

§ 371 Date: Jun. 23, 2005

(30) Foreign Application Priority Data
Dec. 25, 2002 (JP) 2002-374184

(51) Int. Cl. H01L 21/44

(52) U.S. Cl. 438/609

(57) ABSTRACT

In a dye-sensitized photoelectric transfer device having a semiconductor layer and an electrolyte layer between a transparent conductive substrate and a counter conductive substrate, the semiconductor layer is composed of titania nanotubes, and a sensitizing dye is retained by the titania nanotubes. The titania nanotubes preferably have an anatase-type crystalline form. The dye-sensitized photoelectric transfer device is used as a dye-sensitized solar cell.

### TECHNICAL FIELD

The present invention relates to a dye-sensitized photoelectric transfer device and a manufacturing method thereof, especially suitable for application to dye-sensitized solar cells.

### BACKGROUND ART

Various solar cells have been developed as energy source using sunlight in place of fossil oil. The most popular solar cells use silicon, and a number of such solar cells are commercially available. They are roughly classified to crystalline silicon solar cells using single crystal silicon or polycrystal silicon and amorphous silicon solar cells.

Solar cells have often used single crystal silicon or polycrystal silicon, i.e. crystalline silicon.

In crystalline silicon solar cells, photoelectric transfer efficiency, which exhibits the performance of converting light (sun) energy to electrical energy, is higher than that of amorphous silicon solar cells. However, since crystalline silicon solar cells need much energy and time for crystal growth, they are disadvantageous in terms of the cost because of the low productivity.

Amorphous silicon solar cells are advantageous in higher light absorption, wider selectable range of substrates and easier enlargement of the scale. However, photoelectric transfer efficiency of amorphous silicon solar cells is lower than that of crystalline silicon solar cells. Furthermore, although amorphous silicon solar cells are higher in productivity than crystalline silicon solar cells, they need an evacuation process for the manufacture, and still consume high energy.

In addition, these solar cells involve the problem of environmental pollution because toxic materials such as gallium, arsenic and silane gas are used for the manufacture.

On the other hand, there have been long researches of solar cells using organic materials to solve the above problems. However, many of them have poor photoelectric transfer coefficient as low as 1% and have not be turned into practical use.

Among them, dye-sensitized solar cells introduced on Nature Vol. 353, p. 737, (1991) are remarked because they have been proved enable to realize photoelectric transfer efficiency as high as 10% and are considered manufacturable economically. These dye-sensitized solar cells are wet solar cells, i.e. electrochemical photocells, in which a porous titania (titanium oxide TiO₂) film spectrally sensitized by using ruthenium complex as sensitizing dye is used as a photo electrode (called a semiconductor electrode as well).

Recently, special tubular titania of a nanometer size has been developed by Kasuga et al. (Japanese Patent Laid-open Publications JP-H10-152323 and JP2002-241129). In addition, it has been known that vacancies of a nanometer size represented by carbon nanotube has a special potential field and has strong absorption energy (Journal of the Society of Inorganic Materials, Japan 8, 418-427 (2001)).

However, since the sensitizing dye used in the above-introduced technique is used in the form absorbed by porous titania, it must have acidic substituents such as carboxylic acid, and this has restricted sensitizing dyes usable. The reason of the need for acidic substituents to retain the sensitizing dye on porous titania lies in that the absorption energy of the surface of porous titania is too week to absorb the sensitizing dye, and it is necessary to give electrostatic interaction to the sensitizing dye.

Furthermore, because of the introduction of acidic substituents to the sensitizing dye, the manufacturing cost of such sensitizing dye was inevitably high, and inevitably increased the manufacturing cost of dye-sensitized solar cells.

Moreover, introduction of acidic substituents to sensitizing dye increases the liability to association of sensitizing dyes with each other via the acidic substituents, and brings about the phenomenon of optical quenching of photo-excited electrons, thereby decreasing the injection efficiency of excitation electrons into semiconductors. Therefore, it has been difficult to obtain sufficient effect of enhancing photoelectric transfer efficiency by introduction of the sensitizing dye.

As such, existing dye-sensitized solar cells involve the problem that employable sensitizing dyes are limitative because of their acidic substituents as well as the problem that their practical use are difficult because of high manufacturing costs caused by sensitizing dyes requiring a complicated manufacturing process and limits of enhancement in photoelectric transfer efficiency.

It is therefore an object of the invention to provide a dye-sensitized photoelectric transfer device permitting the use of any desired sensitizing dye, manufactured at a low cost and exhibiting high photoelectric transfer efficiency, as well as a manufacturing method thereof.

### DISCLOSURE OF INVENTION

The Inventors of the present invention made researches to solve the aforementioned problems involved in the existing techniques, and found that the use of titania nanotubes as the semiconductor layer is most effective to enable sensitizing dyes having no acidic substituents. Thus, the Inventors have reached the present invention.

To solve the problems, the present invention provides a dye-sensitized photoelectric transfer device comprising:

a semiconductor layer containing titania nanotubes; and

a sensitizing dye retained by the titania nanotubes.

The present invention also provides a method of manufacturing a dye-sensitized photoelectric transfer device, comprising:

using a semiconductor layer containing titania nanotubes; and

having a sensitizing dye retained by the titania nanotubes.

In the invention, any sensitizing dyes are usable as those to be retained by titania nanotubes without special limitation, either having or not having acidic substituents. Examples of such sensitizing dyes are xanthene-based dyes such as rhodamine B, rose bengal, eosin and Erythrocin; cyanine-based dyes such as quinocyanine and cryptocyanine; basic dyes such as phenosafranine, Capri blue, thiocin and methylene blue; porphyrin-based compounds such as chlorophyll, zinc porphyrin and magnesium porphyrin; azo dyes; phthalocyanine compounds; coumarin-based compounds; Ru bipyridine complex compound; anthraquinone-based dyes; and polycyclic quinone-based dyes. Among them, ruthenium (Ru) bipyridine complex compound is preferable because of its high quantum yield. However, without being limited to it, those dyes can be used alone or as a mixture of two or more kinds of them. Furthermore, those dyes with acidic substituents attached may be used as well.

The sensitizing dye may be retained by titania nanotubes in any form or manner. For example, a typical method is to dissolve any of the above-mentioned sensitizing dyes in a solution such as various kinds of alcohol, various kinds of nitrile, nitromethane, halogenated hydrocarbon, various kinds of ether, dimethyl sulfoxide, various kinds of amide, N-methyl pyrrolidone, 1,3-dimethyl imidazolysinone, 3-methyl oxazolidinone, various kinds of ester, various kinds of carbonic acid ester, various kinds of ketone, hydrocarbon, water, and so on, next immerse the titania nanotubes therein, or coating a semiconductor layer containing titania nanotubes with the dye solution. If greatly excessive sensitizing dye molecules are retained by titania nanotubes, electrons excited by light energy are not injected into titania nanotubes and instead deoxidize the electrolyte. Thus, excessive sensitizing dye molecules rather invite energy loss. Therefore, it is ideal that a single sensitizing dye molecule is retained by each titania nanotube, and the temperature and pressure for retainment can be changed if necessary. For the purpose of reducing association of sensitizing dye particles, a carboxylic acid like deoxycholic acid may be added as well. It is also possible to use an ultrasonic absorbent in parallel.

For the purpose of removing excessively retained sensitizing dye particles, titania nanotubes retaining the sensitizing dye may undergo surface treatment using a kind of amine. Examples of amine system substances are pyridine, 4-tert-butyl pyridine, polyvinyl piridine, and so on. If they are liquids, they can be used either directly or in form of solution in an organic solvent.

Diameters of titania nanotubes are not limitative provided they can retain the sensitizing dye. Typically, however, the diameters range from 5 nm to 80 nm. The titania nanotubes preferably have an anatase crystalline form.

Dye-sensitized photoelectric transfer devices, in general, include a semiconductor layer containing titania nanotubes retaining sensitizing dye and an electrolyte layer between a pair of opposed electrodes. More specifically, a semiconductor layer and an electrolyte layer are provided between a transparent conductive substrate and a conductive substrate as a counter electrode of the transparent conductive substrate, and electric energy is generated by photoelectric transfer between the transparent conductive substrate and the conductive substrate.

The transparent conductive substrate may be made by forming a transparent conductive film on a conductive or non-conductive transparent support substrate, or may be an electrically conductive transparent substrate in its entirety. There is no particular limitation to the material of the conductive substrate, and various kinds of transparent support materials are usable. The conductive substrate preferably has high blocking capability against intruding moisture and gas from outside the photoelectric transfer element, high resistance to the solvent and high weather resistance. Examples of such substrates are transparent inorganic substrates of quartz, glass, or the like, transparent plastic substrates of polyethylene terephthalate, polyethylene naphthalate, polycarbonate, polystyrene, polyethylene, polypropylene, polyphenylene sulfide, polyvinylidene fluoride, tetraacetyl cellulose, phenoxy bromide, kinds of aramid, kinds of polyimide, kinds of polystyrene, kinds of polyarylate, kinds of polysulfone, kinds of polyolefin, and so forth. However, materials of the substrate are not limited to these examples. Taking easier workability and lighter weight into account, a transparent plastic substrate is preferably used as the conductive substrate. There is no particular limitation to the thickness of the conductive substrate. The thickness may be determined freely depending upon the light transmittance, blocking capability between the inside and the outside of the photoelectric transfer element, and other factors.

It is desirable that the transparent conductive substrate has surface resistance as low as possible. More specifically, the surface resistance of the transparent conductive substrate is preferably 500 Ω/□ or less, and more preferably 100 Ω/□ or less. In case the conductive substrate is made by forming a transparent conductive film on a transparent support substrate, known materials can be used. Examples of such materials are indium-tin complex oxide (ITO) fluorine-doped ITO (FTO) and SnO₂. Usable materials are not limited to those examples, and two or more of them can be used in combination as well. For the purpose of reducing the surface resistance of the transparent conductive substrate and thereby enhancing the collecting efficiency, a pattern of metal wiring of high conductivity can be made on the transparent conductive substrate.

Dye-sensitized photoelectric transfer devices are typically configured in form of dye-sensitized solar cells.

According to the invention having the above-summarized configuration, since the semiconductor layer containing titania nanotubes is used, when the semiconductor layer is brought into contact with a solution prepared by dissolving a sensitizing dye in a solvent such as ethanol, the sensitizing dye quickly intrudes inside the titania nanotubes by capillary phenomenon. After the solvent is removed, the sensitizing dye remains in the titania nanotubes, and can stably stay in titania nanotubes with the aid of a unique potential field inside the titania nanotubes. Therefore, special acidic substituents need not be introduced to the sensitizing dye.

Specific surface area of titania nanotubes is 270 m²/g, which is exponentially larger than the specific surface area (50 m²/g) of anatase crystals of porous titania generally used in dye-sensitized solar cells. Therefore, it is possible to increase the quantity of the sensitizing dye absorbed and greatly enhance the photoelectric transfer efficiency.

Since there is no need of introducing acidic substituents into the sensitizing dye, it is possible to suppress association of sensitizing dye particles, thereby alleviate the phenomenon of optical quenching of photo-excited electrons, and efficiently inject excited electrons into the titania nanotubes. This advantage also contributes to enhancing the photoelectric transfer efficiency.

In addition, no need of introducing acidic substituents into the sensitizing dye simplifies the manufacturing process of the sensitizing dye and thereby contributes to great reduction of the manufacturing cost. At the same time, since the need of introduction of acidic substituents is removed, it is easy to use new sensitizing dyes having been unknown heretofore, and the liberty of choice of sensitizing dyes is broadened.

### BRIEF DESCRIPTION OF DRAWINGS

FIG. 1 is a cross-sectional view showing a dye-sensitized solar cell according to an embodiment of the invention.

FIG. 2 is a diagram schematically showing a titania nanotube retaining a sensitizing dye, which constitutes a semiconductor layer of a dye-sensitized solar cell according to an embodiment of the invention.

FIG. 3 is a diagram schematically showing porous titania retaining a sensitizing dye, which constitutes a semiconductor layer of an existing dye-sensitized solar cell.

### BEST MODE FOR CARRYING OUT THE INVENTION

An embodiment of the invention will now be explained below with reference to the drawings.

A dye-sensitized photoelectric transfer device according to the embodiment uses a semiconductor layer composed of titania nanotubes retaining a sensitizing dye. Diameter of each titania nanotube is approximately 5-80 nm, and its length is normally 50-150 nm. Wall thickness of the titania nanotube is normally 2-10 nm. Crystal form of this titania nanotube is the anatase type.

Titania nanotubes can be obtained by alkali treatment of titania powder referring to known methods (Japanese Laid-open Publication JP-H10-152323 and Japanese Laid-open Publication JP2002-241129), for example.

Alkali treatment is usually carried out by immersing titania powder for 1-50 hours under the conditions: concentration of sodium hydroxide being 13-65 wt % and temperature being 18-180° C. If the concentration of sodium hydroxide is lower than 13 wt %, too much time will be taken for tubes to form. If the concentration exceeds 65 wt %, it becomes difficult to generate tubular structures. If the temperature is lower than 18° C., the reaction time for generation becomes longer. If the temperature exceeds 160° C., it becomes difficult to obtain tubular structures. This alkali treatment is carried out for 2-20 hours preferably under the conditions: concentration of sodium hydroxide being 18-55 wt % and temperature being 50-120° C., or more preferably under the conditions: concentration of sodium hydroxide being 30-50 wt % and temperature being 50-120° C.

The semiconductor layer composed of titania nanotubes can be fabricated, referring to known methods (H. Arakawa, “Latest Techniques of Dye-sensitized Solar Cells” (C.M.C.) p. 45-47 (2001)), for example, by mixing titania nanotubes dispersed in an ethanol solution with polyethylene oxide (PEO) as a bonding agent, then uniforming the mixture with a planet ball mill, next printing the mixture on a fluorine-doped conductive glass substrate (having a sheet resistance of 30 Ω/□) by screen printing, for example, and sintering it at 450° C.

To ensure that the semiconductor layer of titania nanotubes can retain any arbitrary sensitizing dye, an exemplary method dissolves a sensitizing dye in an appropriate solvent such as dimethylformamide; then immerses the semiconductor layer of titania nanotubes in the solution; leaves the semiconductor layer there until the semiconductor layer is sufficiently impregnated with and absorbs the dye; thereafter removes it; and dries it after washing, if necessary.

The semiconductor layer composed of titania nanotubes may retain one or more kinds of sensitizing dyes.

In the dye-sensitized photoelectric transfer device according to the first embodiment, the semiconductor layer composed of titania nanotubes and an electrolyte layer are provided between a transparent conductive substrate and a conductive substrate as a counter electrode of the transparent conductive substrate. When light enters through the transparent conductive substrate, the device can generate electric energy between the transparent conductive substrate and the counter conductive substrate by photoelectric transfer.

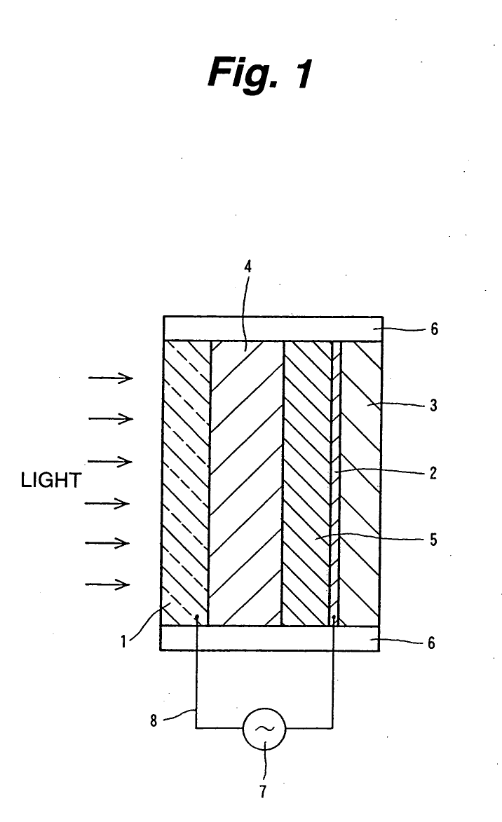

The dye-sensitized photoelectric transfer device according to the embodiment is typically configured as a dye-sensitized solar cell. FIG. 1 shows this dye-sensitized solar cell.

As shown in FIG. 1, the dye-sensitized wet solar cell includes a semiconductor layer 4 made of titania nanotubes retaining a sensitizing dye and an electrolyte layer 5 between a transparent conductive substrate 1 and a substrate 3 having a conductive film 2 as a counter electrode of the transparent conductive substrate 1. These elements are protected by a case 6. The transparent conductive substrate 1 and the conductive film 2 are connected to each other by a conducting wire, and here is formed a current circuit 8 having an ammeter 7.

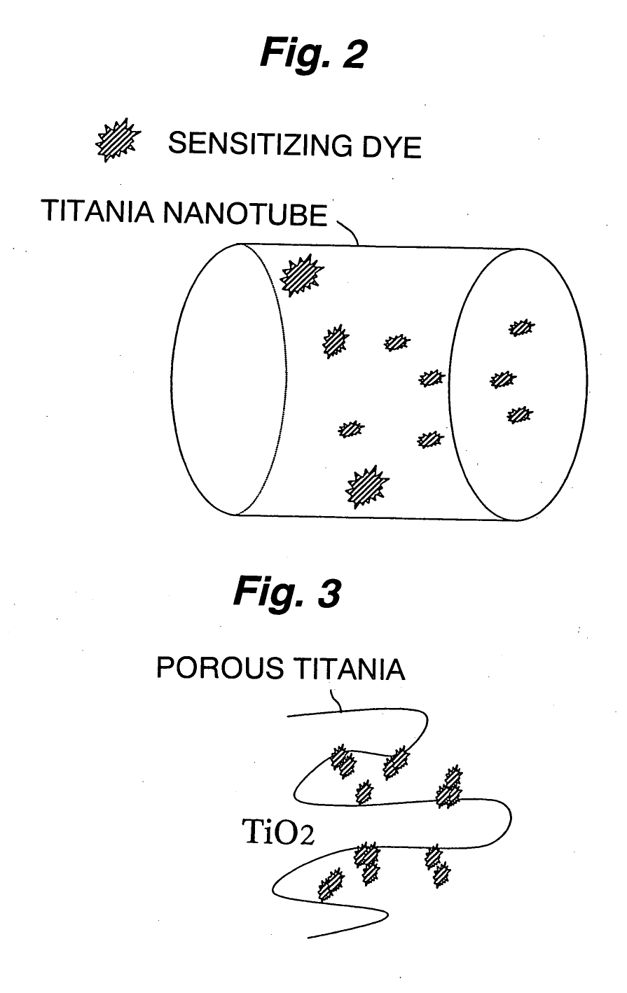

The semiconductor layer 4 made of titania nanotubes retaining sensitizing dye particles may have a bundle structure in which titania nanotubes retaining sensitizing dye particles are bound together at their outer wall surfaces. The sensitizing dye can be retained not only inside the titania nanotubes but also on their outer wall surfaces and in vacancies among tubes in the bundle structure. FIG. 2 schematically shows a titania nanotube retaining sensitizing dye particles.

Geometry of the semiconductor layer 4 composed of titania nanotubes retaining a sensitizing dye is not limited to a specific geometry. It may take various forms like a film, plate, column, cylinder, and so on.

The transparent conductive substrate 1 may be either a transparent substrate having a transparent conductive film or a substrate that is entirely transparent and conductive. An example of a transparent substrate having a transparent conductive film may be made by forming a thin film of indium oxide, tin oxide, indium tin oxide, or the like, on a heat-resistant substrate of glass, plastic such as polyethylene terephthalate (PET), or the like. As an entirely transparent and conductive substrate, a fluorine-doped conductive glass substrate, for example, may be used. There is no specific limitation to the thickness of the transparent conductive substrate 1. However, it is normally around 0.3-5 mm.

The conductive film 2 forming the counter electrode may be made of any material known as counter electrodes for existing solar cells, such as aluminum, silver, tin, indium, or the like. However, preferable materials are platinum, rhodium, ruthenium, ruthenium oxide, carbon, etc. having a catalytic function to promote deoxidization of oxidization type redox ions such as I₃ ions for example. The film of such a metal is preferably formed by physical vapor deposition or chemical vapor deposition on the surface of a conductive material.

The electrolyte layer 5 interposed between the semiconductor layer 4 and the conductive film 2 made be made of any selected from materials conventionally used as electrolyte layers of solar cells. An example of such materials is the substance prepared by dissolving iodine and potassium iodide into a mixed solvent of polypropylene carbonate by 25 wt % and ethylene carbonate by 75 wt %.

The dye-sensitized solar cell has the operation mechanism explained below.

When sunlight enters into the transparent conductive substrate 1, its light energy excites the sensitizing dye retained by titania nanotubes in the semiconductor layer 4, and generates electrons. Since the transparent conductive substrate 1 and the conductive film 2 are connected by the current circuit 8, the electrons generated flow into the conductive film 2 through the nanotubes in the semiconductor layer 4. It is therefore possible to extract electric energy between the transparent conductive substrate 1 and the conductive film 2.

The dye-sensitized solar cell having the above-explained structure can generate electricity with as high a photoelectric transfer efficiency as 10.0% or more, for example, when pseudo sunlight (AM (Air Mass): 1.5, 100 mW/cm²) from through the transparent conductive substrate 1. This photoelectric transfer efficiency varies with thickness of the semiconductor layer 4, state of the semiconductor layer 4, mode of absorption of the sensitizing dye, sort of the electrolyte layer 5, and so on. Therefore, more enhancement can be expected by selecting optimum conditions of these factors.

Since the dye-sensitized solar cell uses the semiconductor layer 4 composed of titania nanotubes, once the semiconductor layer 4 is immersed into a solution prepared by dissolving an arbitrary sensitizing dye in a solvent of ethanol or the like, the sensitizing dye quickly intrude into the titania nanotubes due to capillary phenomenon. The sensitizing dye remains in the titania nanotubes even after the solvent is removed, and can stably stay in the titania nanotubes with the aid of a potential field inside peculiar to the inside of a tube. Therefore, the solar cell need not introduce special acidic substituents into the sensitizing dye.

Moreover, since the specific surface area of titania nanotubes is as large as 270 m²/g, that is exponentially larger than that of the specific surface area (50 m²/g) of anatase crystals of porous titania generally used in dye-sensitized solar cells, quantity of the sensitizing dye absorbed increases, and the photoelectric transfer efficiency is enhanced significantly.

Furthermore, no need of introducing acidic substituents into the sensitizing dye suppresses association of the sensitizing dye particles and optical quenching of photo-excited electrons among molecules, and enables efficient injection of excited electrons into titania nanotubes. This also contributes to enhancing the photoelectric transfer efficiency. That is, since the individual sensitizing dye particles adhere to different positions without associating with each other as shown in FIG. 2, optical quenching of photo-excited electrons among molecules by light entering into the sensitizing dye is suppressed. For comparison purposes, FIG. 3 schematically shows how a conventional dye-sensitized solar cell using a porous titania thin film as its semiconductor layer retain sensitizing dye particles in the porous titania thin film. As shown in FIG. 3, sensitizing dye particles associate and form aggregates.

In addition, no need of introducing acidic substituents simplifies the manufacturing process of the sensitizing dye and enables substantial reduction of the manufacturing cost of the sensitizing dye. Simultaneously, the removal of requirements of introducing acidic substituents makes it easy to introduce unknown, novel sensitizing dyes.

Hereafter, some specific examples of the invention will be explained. However, the invention is not limited to these specific examples.

### Embodiment

Referring to Japanese Patent Laid-open Publication JP-H10-152323, titania nanotubes were fabricated as explained below. Commercially available crystal titania (mean grain size: 20 nm; specific surface area: 50 m²/g) was immersed into 40 wt % sodium hydroxide solution and left to react in a hermetic container for 20 hours at 110° C.

Next referring to H. Arakawa, “Latest Techniques of Dye-sensitized Solar Cells” (C.M.C.) p. 45-47 (2001), paste of titania nanotubes was prepared as follows. Titania nanotubes were dispersed in an ethanol solution to contain 11 wt % of titania nanotubes. Then, the solution was added with PEO having the molecular mass of 500 thousands, and mixed homogenously in a planet ball mill to obtain a viscosity-enhanced paste of titania nanotubes.

The paste of titania nanotubes obtained was coated on a fluorine-doped conductive glass substrate (sheet resistance: 30 Ω/□) over the area of 1 cm×1 cm by screen printing, then maintained at 450° C. for 30 minutes, and sintered on the conductive glass substrate to obtain a titania nanotube film.

Thereafter, the titania nanotube film was immersed in a solution prepared by dissolving 5×10⁻⁴ M of 5,10,15,20-tetraphenylporphynato zinc chain (ZnTPP) as a dye not having acidic substituents in dimethyl formamide, left there at 80° C. for 12 hours, then rinsed with methanol under argon atmosphere, and dried. Similarly, the titania nanotube film was immersed in a solution prepared by dissolving cis-bis(2,2′-bipyridine)-dicyanate ruthenium (N) by 5×10⁻⁴ M, respectively, as dyes having no acidic substituents in dimethyl formamide, left there at 80° C. for 12 hours, then rinsed with methanol under argon atmosphere, and dried.

Further, the titania nanotube film was immersed in a solution prepared by dissolving 5×10⁻⁴ M of 5,10,15,20-tetrakis-(4-carboxyphenyl)porphyrin (ZnTCPP) as a dye having acidic substituents in ethanol, left there at 80° C. for 12 hours, then rinsed with methanol under argon atmosphere, and dried. Similarly, the titania nanotube film was immersed in a solution prepared by dissolving cis-bis((4,4′-dicarboxylic acid) 2,2′-bipyridine)-dicyanate ruthenium (N3) by 5×10⁻⁴ M, respectively, as dyes having acidic substituents in dimethyl formamide, left there at 80° C. for 12 hours, then rinsed with methanol under argon atmosphere, and dried.

Then, dye-sensitized solar cells having the structure shown in FIG. 1 were prepared by using a counter electrode made by depositing a 10 μm thick platinum film on an ITO-deposited substrate by sputtering and using an electrolyte prepared by dissolving a mixture of 0.38 g of iodine and 2.49 g of potassium iodide in 30 g of mixture of 25 wt % of propylene carbonate and 25 wt % of ethylene carbonate.

### COMPARATIVE EXAMPLE

An ordinary porous titania film was used as the semiconductor layer. Titania paste was prepared in the following manner, referring to H. Arakawa, “Latest Techniques of Dye-sensitized Solar Cells” (C.M.C.) p. 45-47 (2001). 125 ml of titanium isopropoxyde was slowly dropped into 750 ml of 0.1 M nitric acid solution while stirred at the room temperature. After the dropping, the solution was moved to a thermostatic vessel, and stirred for 8 hours. Thereby, a cloudy, semi-transparent sol solution was obtained. The sol solution was left to cool down to the room temperature, then filtered through a glass filter, and 700 ml thereof was measured up. The sol solution obtained was moved to an autoclave, then annealed at 220° C. for 12 hours, and thereafter dispersed by ultrasonic treatment for one hour. Subsequently, the solution was condensed by an evaporator at 40° C. until the content of titania becomes 11 wt %. The condensed sol solution was added PEO having the 500 thousand molecular mass and mixed homogenously in a planet ball mill to obtain a viscosity-enhanced titania paste.

The titania paste obtained was coated on a fluorine-doped conductive glass substrate (sheet resistance: 30 Ω/□) over the area of 1 cm×1 cm by screen printing, then maintained at 450° C. for 30 minutes, and sintered on the conductive glass substrate to obtain a porous titania film.

The porous titania film was immersed in a solution prepared by dissolving 5×10⁻⁴ M of 5,10,15,20-tetraphenylporphynato zinc chain (ZnTPP) as a dye not having acidic substituents in dimethyl formamide, left there at 80° C. for 12 hours, then rinsed with methanol under argon atmosphere, and dried. Similarly, the porous titania film was immersed in a solution prepared by dissolving cis-bis (2,2′-bipyridine)-dicyanate ruthenium (N) by 5×10⁻⁴ M, respectively, as dyes having no acidic substituents in dimethyl formamide, left there at 80° C. for 12 hours, then rinsed with methanol under argon atmosphere, and dried.

Further, the porous titania film was immersed in a solution prepared by dissolving 5×10⁻⁴ M of 5,10,15,20-tetrakis-(4-carboxyphenyl)porphyrin (ZnTCPP) as a dye having acidic substituents in ethanol, left there at 80° C. for 12 hours, then rinsed with methanol under argon atmosphere, and dried. Similarly, the porous titania film was immersed in a solution prepared by dissolving cis-bis((4,4′-dicarboxylic acid) 2,2′-bipyridine)-dicyanate ruthenium (N3) by 5×10⁻⁴ M, respectively, as dyes having acidic substituents in dimethyl formamide, left there at 80° C. for 12 hours, then rinsed with methanol under argon atmosphere, and dried.

Then, dye-sensitized solar cells having the structure similar to that of FIG. 1 were prepared by using a counter electrode made by depositing a 10 μm thick platinum film on an ITO-deposited substrate by sputtering and using an electrolyte prepared by dissolving a mixture of 0.38 g of iodine and 2.49 g of potassium iodide in 30 g of mixture of 25 wt % of propylene carbonate and 75 wt % of ethylene carbonate.

The dye-sensitized solar cells prepared as the examples and comparative examples as explained above were operated by using pseudo sunlight (AM: 1.5; 100 mW/cm²). Its results are shown in Table 1. In Table 1, short circuit current means the current measured by short-circuiting the opposed electrodes. Open voltage means the voltage generated by opening the opposed electrodes. Photoelectric transfer efficiency is defined by the following equation.

Photoelectric transfer efficiency (%)=(output electric energy/incident sunlight energy)×100

TABLE 1

| | | | | Photoelectric |
|---|---|---|---|---|
| | Sensitizing | Short circuit | Open voltage | transfer |
| Titania film | dye | current (mA) | (V) | efficiency (%) |
| Nanotubes | ZnTPP | 5.0 | 0.6 | 1.8 |
| Nanotubes | N | 17.2 | 0.75 | 10.2 |
| Nanotubes | ZnTCPP | 4.8 | 0.5 | 1.44 |
| Nanotubes | N3 | 15.5 | 0.7 | 7.6 |
| Porous | ZnTPP | 0.1 | 0.3 | 0.018 |
| Porous | N | 0.12 | 0.28 | 0.016 |
| Porous | ZnTCPP | 4.7 | 0.6 | 1.7 |
| Porous | N3 | 14.5 | 0.69 | 7.0 |

Heretofore, an embodiment of the invention has been explained specifically, but the invention is not limited to this embodiment but it contemplates various changes and modifications based upon the technical concept of the present invention.

Fog example, numerical values, structures, shapes, materials, source materials, processes, and so on, are not but mere examples, and any other appropriate numerical values, structures, shapes, materials, source materials, processes, and so on, may be employed, if necessary.

As described above, according to the invention, any desired material is usable as the sensitizing dye by using a semiconductor layer containing titania nanotubes and retaining sensitizing dye particles in the titania nanotubes. This removes the requirement of introducing acidic substituents, and thereby contributes to reduction of the manufacturing cost and the manufacturing cost of the dye-sensitized photoelectric transfer device. Further, the invention can enhance the photoelectric transfer efficiency of the dye-sensitized photoelectric transfer device because it uses titania nanotubes having a very large specific surface area and because it can suppress association of sensitizing dye particles by selecting a sensitizing dye having no acidic substituents.

1. A dye-sensitized photoelectric transfer device comprising:
a semiconductor layer containing titania nanotubes; and
a sensitizing dye retained by the titania nanotubes.

2. The dye-sensitized photoelectric transfer device according to claim 1 wherein the sensitizing dye has no acidic substituents.

3. The dye-sensitized photoelectric transfer device according to claim 1 wherein the titania nanotubes retain at least two kinds of sensitizing dyes.

4. The dye-sensitized photoelectric transfer device according to claim 1 or 2 wherein particles of the sensitizing dye do not associate with each other.

5. The dye-sensitized photoelectric transfer device according to claim 1 wherein each of the titania nanotubes has a diameter from 5 nm to 80 nm.

6. The dye-sensitized photoelectric transfer device according to claim 1 wherein the titania nanotubes are in form of an anatase type crystal.

7. The dye-sensitized photoelectric transfer device according to claim 1 wherein the semiconductor layer and an electrolyte layer are provided between a pair of opposed electrodes.

8. The dye-sensitized photoelectric transfer device according to claim 1 wherein the semiconductor layer and an electrolyte layer are provided between a transparent conductive substrate and a conductive substrate as the counter electrode of the transparent conductive substrate to generate electric energy between the transparent conductive substrate and the conductive substrate by photoelectric transfer.

9. The dye-sensitized photoelectric transfer device according to claim 8 wherein the transparent conductive substrate is a transparent substrate having a transparent conductive film.

10. The dye-sensitized photoelectric transfer device according to claim 8 or 9, which is configured as a dye-sensitized solar cell.

11. A method of manufacturing a dye-sensitized photoelectric transfer device, comprising:
using a semiconductor layer containing titania nanotubes; and
having a sensitizing dye retained by the titania nanotubes.
